(19) United States
(12) Patent Application Publication
(10) Pub. No.: US 2010/0019783 A1
(43) Pub. Date: Jan. 28, 2010

(54) METHOD, DETECTOR AND SYSTEM FOR MEASURING A SAMPLE CONCENTRATION

(75) Inventors: Nicolaas Petrus Willard, Eindhoven (NL); Ivon Franciscus Helwegen, Herten (NL); Milan Saalmink, Eindhoven (NL); Teunis Johannes Vink, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: Koninklijke Philips Electronics N.V., Eindhoven (NL)

(21) Appl. No.: 12/521,779

(22) PCT Filed: Dec. 20, 2007
(86) PCT No.: PCT/IB07/55242

§ 371 Date: Jun. 30, 2009

(30) Foreign Application Priority Data
Jan. 4, 2007 (EP) 07100097.0

(51) Int. Cl. G01R 27/08; G01R 27/00

(52) U.S. Cl. 324/693; 702/65

(57) ABSTRACT

A method for measuring a concentration of a sample in a sample mixture, the method comprising bringing the sample mixture in contact with an organic semiconductor transistor, applying measurement signals to electrodes of the transistor for enabling measuring a drain current through the transistor, applying a refreshment signal to the gate electrode for counteracting effects imposed on the transistor during the measurement signal, measuring the drain current, applying an adaptation to at least one of said signals for stabilizing the drain current, and determining the concentration based on the adaptation.

### TECHNICAL FIELD OF THE INVENTION

The invention relates to a method for measuring a concentration of a sample in a sample mixture, the method comprising bringing the sample mixture in contact with an organic semiconductor transistor, applying signals to electrodes of the transistor, measuring a drain current through the transistor, determining the concentration and stabilizing the drain current.

The invention further relates to a detector and a system for measuring the concentration of the sample.

### BACKGROUND OF THE INVENTION

US patent application 2002/0116982 describes an organic field effect transistor (OFET) for detecting odors, vapors and gases. The US patent application deals with the problem that OFETs are subject to drift and threshold shift as a function of time by coupling a feedback circuit between an output of the organic transistor and an input of the organic transistor to generate a feedback signal which stabilizes the output signal of the odor-sensitive organic transistor for time drift. When the detector is in a non-sensing mode, i.e. no gas is supplied to the transistor, the feedback circuit stabilizes the output signal. When the detector is in a sensing mode, the feedback circuit is switched off. It is a problem of the detector of the US patent application that it does not prevent drift during the measurement.

A method of recovering a transistor to its initial properties is known from Brown et al., Synth. Met., 88, 37 (1997). Brown et al. disclose recovery of the transistor to its initial properties by applying a refreshment pulse.

### SUMMARY OF THE INVENTION

It is an object of the current invention to provide a method as described in the opening paragraph, which is capable of preventing drift during the measurement. This object is achieved by providing a method for measuring a concentration of a sample in a sample mixture, the method comprising bringing the sample mixture in contact with an organic semiconductor transistor, applying measurement signals to electrodes of the transistor for enabling measuring a drain current through the transistor, applying a refreshment signal to the gate electrode for counteracting effects imposed on the transistor during the measurement signal, measuring the drain current, applying an adaptation to at least one of said signals for stabilizing the drain current, and determining the concentration based on the adaptation.

The drain current is measured during the measurement signal. When no sample mixture is in contact with the organic semiconductor, the drain current will slowly change due to the occurring drift. The refreshment signal serves to counteract the effect of the drift that occurred during the preceding measurement signal. As a result the drain current remains relatively constant from measurement to measurement. The equilibrium thus obtained, depends on the initial state of the transistor and the parameters of the two signals. When a sample mixture makes contact with the organic semiconductor, this will result in a deviation from the equilibrium. By adapting at least one of the signals, the equilibrium can be restored. The required adaptation depends on the effect of the gas mixture on the equilibrium, which effect depends on the concentration of the sample. The sample concentration may thus be derived from the required adaptation.

The adaptation may comprise adapting a level of a measurement signal and/or the refreshment signal. The adaptation may also comprise adapting a duration of the measurement signals and/or a duration of the refreshment signal.

According to a second aspect of the invention, a detector is provided for performing the method according to the invention. In an embodiment the detector is part of a larger system for measuring a concentration of a sample mixture. The system comprises an input for receiving the sample mixture, a first sector with a first detector according to the invention for interacting with a first portion of the sample mixture and, a second sector with a filter for filtering the sample out of a second portion of the sample mixture to obtain a filtered sample mixture, a second detector according to the invention for interacting with the filtered sample mixture, and an output for making a comparison between the adaptation to the at least one signal of the first detector and the adaptation to the at least one signal of the second detector, and determining and providing the concentration based on the comparison.

This system with two sectors makes it possible to measure the sample concentration very accurately, even when the sample is part of a complex sample mixture. In one sector the complete sample mixture is analyzed and the effect of the complete sample mixture on the transistor is registered. In the other sector the sample is filtered out of the sample mixture, the filtered sample mixture is analyzed and the effect of the filtered sample mixture on the transistor is registered. The difference in required adaptation for both detectors represents the sample concentration. The sample concentration obtained with this system is thus corrected for the influence of other elements in or the temperature of the sample mixture.

These and other aspects of the invention are apparent from and will be elucidated with reference to the embodiments described hereinafter.

### BRIEF DESCRIPTION OF THE DRAWINGS

In the drawings:

FIG. 1a shows a transistor configuration with an organic semiconductor for use with the invention,

FIG. 1b shows an organic semiconductor transistor with trapped charges,

FIG. 2a shows a typical progress of the drain current over time

FIG. 2b shows a typical progress of the drain current over time when a sample mixture is brought into contact with the transistor,

FIG. 3a shows a typical progress of the drain current over time when the method according to the invention is applied,

FIG. 3b shows a typical progress of the drain current over time when a sample mixture is brought into contact with the transistor and the method according to the invention is applied,

FIG. 4 shows a detector according to the invention,

FIGS. 5 to 8 show different possibilities for adapting the gate voltage to varying sample concentrations in accordance with the method according to the invention, and.

FIG. 9 shows a system with two detectors according to the invention.

### DETAILED DESCRIPTION OF THE INVENTION

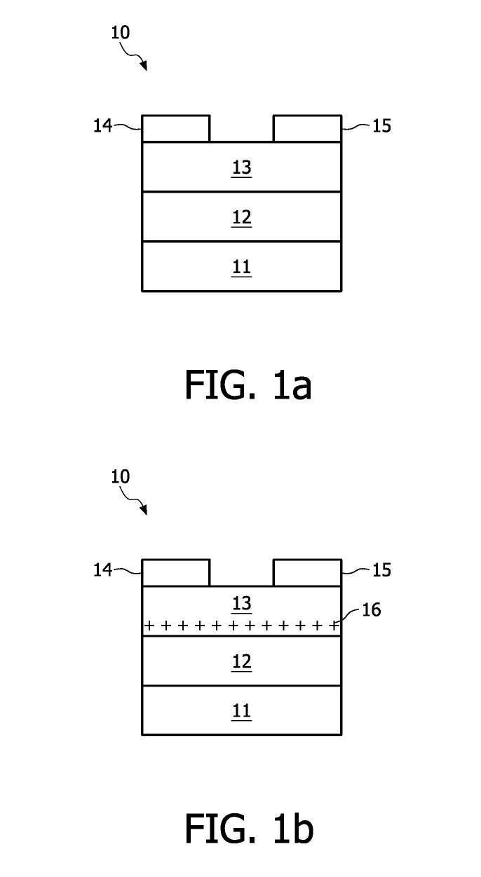

FIG. 1a shows a transistor configuration 10 with an organic semiconductor 13 for use with the invention. The organic semiconductor transistor 10 comprises a gate electrode 11, a source electrode 14 and a drain electrode 15. The transistor 10 further comprises an insulator layer 12 and a semiconductor body 13. A voltage may be applied to the gate electrode to control the conductivity of the semiconductor body 13. The level of the drain current, I_{d}, depends on the source drain voltage, V_{ds}, the gate voltage, V_{g}, and the chemical composition of the semiconductor body 13. The chemical composition of the semiconductor body 13 depends on the sample concentration in the sample mixture applied to the transistor 10. The drain current, I_{d}, thus is a measure for the sample concentration.

FIG. 1b shows an organic semiconductor transistor 10 with trapped charges 16. During the use of the transistor 10, charges get trapped at the gate-isolator interface, which results in a slow and continuous decrease of the drain current.

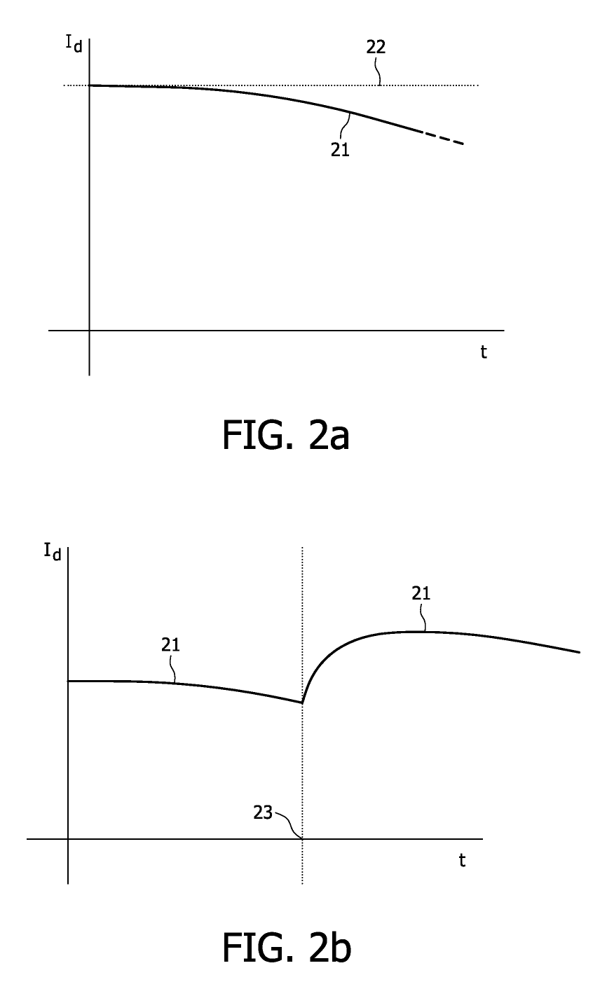

FIG. 2a shows a typical progress of the drain current 21 over time. When a constant voltage is applied to the gate 11 of the transistor 10, the drain current 21 slowly and continuously decreases. After a while the drain current level 21 differs from the initial drain current 22. In US 2002/0116982, a compensation circuit stabilizes the output signal for time drift when the detector does not function as a gas sensor. According to the current invention, another method for dealing with the drift is provided.

FIG. 2b shows a typical progress of the drain current 21 over time when a sample mixture is brought into contact with the transistor 10. During the complete time span of FIG. 2b, the gate voltage, V_{g}, is at a constant level. At t=0,the drain current 21 is at its initial value. As time progresses, the drain current level 21 begins to drift. At a particular moment 23 a sample mixture is brought into contact with the transistor 10. As a result the chemical composition of the semiconductor body 13 changes which results in a change of the drain current level 21. Dependent on the constituents of the sample mixture and on the type of semiconductor material, the applying of the sample mixture may also result in a drop of the drain current level 21. A short while after the applying of the sample mixture, the alteration of the chemical composition of the semiconductor body 13 is completed and the drain current level 21 arrives at its maximum. Due to the still continuing drift, the drain current level 21 then starts slowly decreasing again.

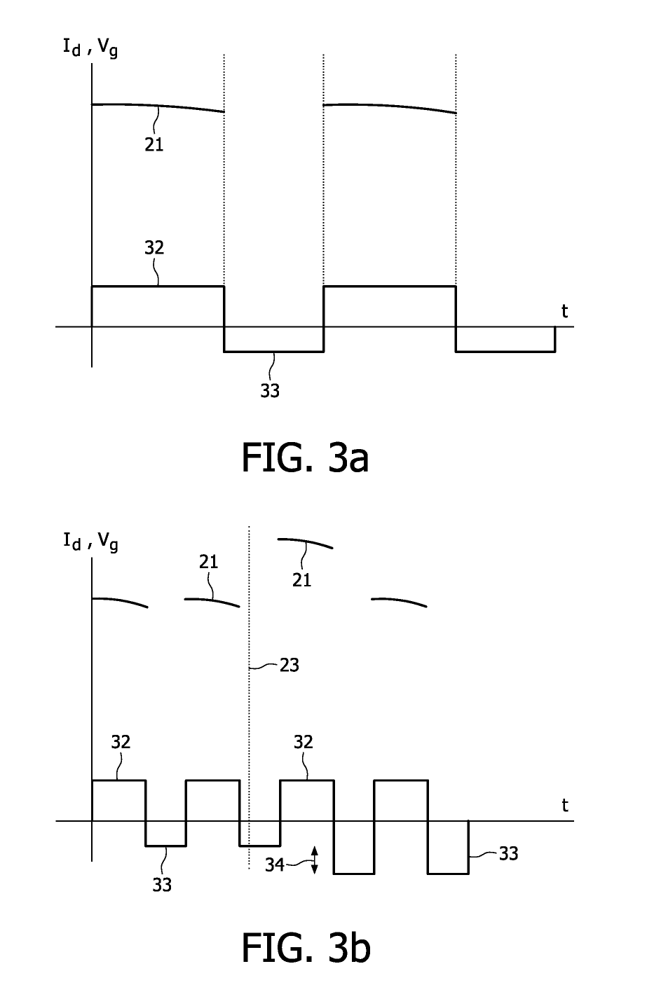

FIG. 3a shows a typical progress of the drain current 21 over time when the method according to the invention is applied. FIG. 3 also shows the gate voltage, V_{g}, applied to the transistor when performing the method. The method according to the invention comprises a pulsed measurement. The pulsed measurement comprises two signals. A measurement signal 32 will force the necessary voltages to the source, drain and gate electrodes on the transistor 10 to measure its electrical properties, such as the drain current 21. As can be seen in FIG. 3a, during the measurement signal 32 the drain current 21 shows little bit of drift. After the measurement, a refreshment signal 33 is applied to the transistor. The voltage level and duration of the refreshment signal 33 is such that the transistor is recovered to its initial properties. If the sample concentration remains constant, the drain current level 21 during a subsequent measurement signal will be substantially equal to the drain current level 21 during the previous measurement signal 32, and no adaptation of the applied voltages is required.

FIG. 3b shows a typical progress of the drain current 21 over time when a sample mixture is brought into contact with the transistor 10 and the method according to the invention is applied. During the first two measurement signals 32, the situation is the same as shown in FIG. 3a. At a particular moment 23, a sample mixture is brought into contact with the transistor 10. As a result the chemical composition of the semiconductor body 13 changes which results in a change of the drain current level 21 measured during the subsequent measurement signal. When a change in the drain current level 21 is detected, the height or duration of at least one of the signals is adapted to bring the drain current level back to its initial value. In FIG. 3b, an adaptation 34 of the height of the refreshment signal is applied. Higher sample concentrations cause larger variations of the drain current and require a larger adaptation to stabilize the drain current. The adaptation required for this stabilization may thus be used as a measure of the sample concentration.

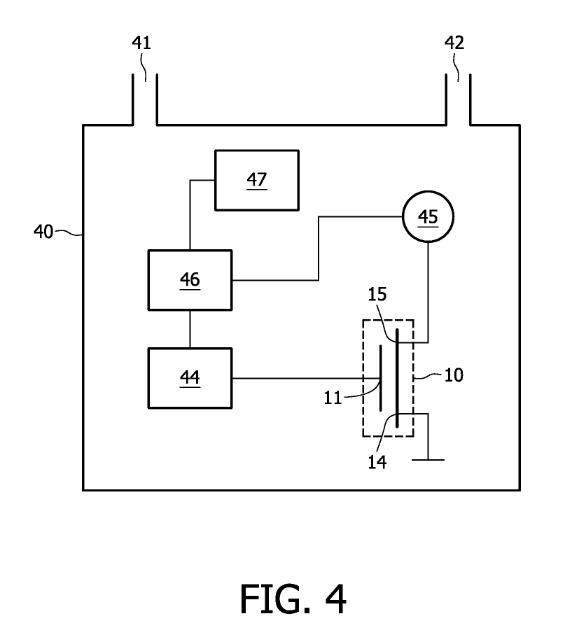

FIG. 4 shows a detector 40 according to the invention. The detector 40 is, for example, a breath analysis device for detecting NO. Similar devices may be used for measuring other elements in other gases, liquids or water. The detector 40 comprises a gas inlet 41 for enabling a user to exhale air into. After the analysis the air leaves the detector 40 via the gas outlet 42. For the analysis, the gas is guided along the transistor 10. The pulsed gate voltage, V_{g}, is applied to the gate 11 of the transistor by a voltage source 44. A current detector 45 measures the drain current, I_{d}, through the drain 15 and source 14. The compensation circuit 46 receives the measured drain current, I_{d}, instructs the voltage source 44 to adapt the signals and provides a copy of the adaptation instructions to the processing unit 47. The processing unit 47 converts the adaptation instructions into a corresponding NO concentration.

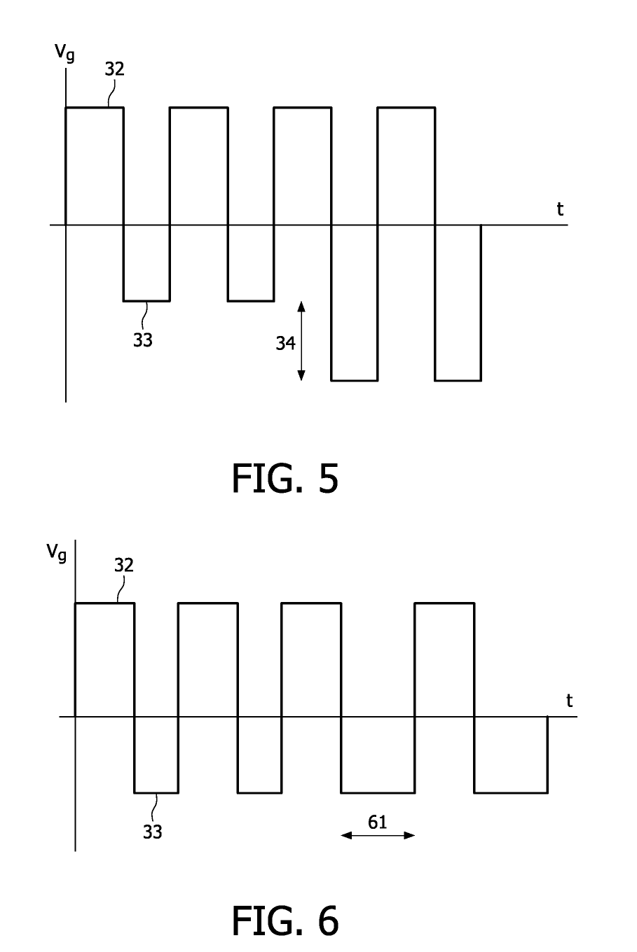

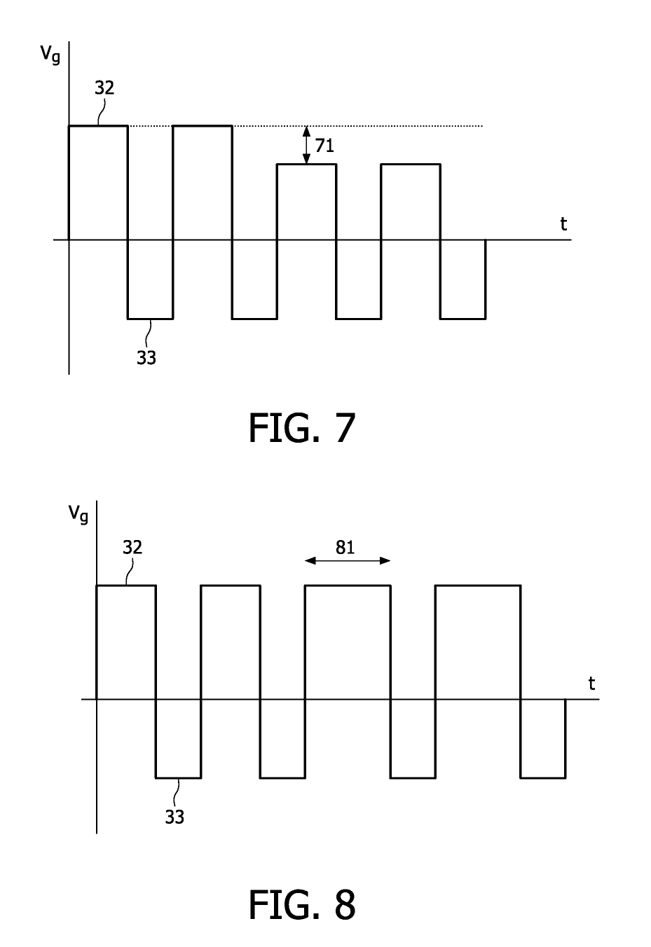

FIGS. 5 to 8 show different possibilities for adapting the gate voltage, V_{g}, to varying sample concentrations in accordance with the method according to the invention. In FIG. 5, the amplitude of the refreshment signal is changed. In the figure, the adaptation 34 is an increase of the amplitude of the refreshment signal (more negative). Depending on the semiconductor material, the sample material and whether the sample concentration increases or decreases, the amplitude is increased or decreased. In FIG. 6, the duration 71 of the refreshment signal is changed to stabilize the drain current. In FIGS. 7 and 8, the adaptation respectively comprises an amplitude decrease 71 or adaptation of the signal duration 81 of the measurement signal. It is to be noted that two or more of the four possible adaptations, shown in FIGS. 5 to 8, may be combined. The effect of the sample on the drain current may alternatively be neutralized by adapting the signals applied to the source and drain of the transistor.

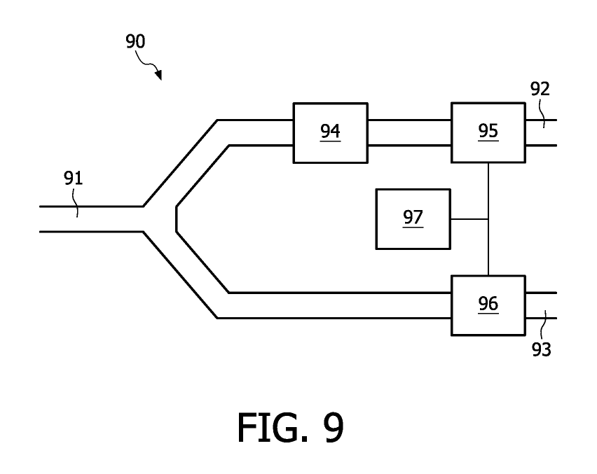

FIG. 9 shows a system 90 with two detectors 95, 96 as described in FIG. 4. The user exhales air into the gas inlet 91 of the system 90. In the system 90, two separate paths are provided. One of the paths leads to an NO-filter 94 for filtering the NO out of the air. The filtered air goes into a first detector 95. The other path leads the air directly to a second detector 96. In both detectors 95, 96 the air will have an effect on the drain current and the compensation unit will adapt the gate voltages. Due to filtering out the NO, the effect of the air on the drain current in the first detector 95 will differ from the effect of the air on the drain current in the second detector 96. These different effects are compensated by different adaptations of the measurement and/or refreshment pulses. An output unit 97 receives the adaptations from the detectors 95, 96, determines the concentration of the sample based on a comparison of the two adaptations and provides the concentration to the user, e.g., via an LCD display. It is to be noted that when using the detector 40 shown in FIG. 4 for this system, the processing unit 47 is not needed and may be left out of the detectors 95, 96.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the claims enumerating several means, several of these means may be embodied by one and the same item of hardware. The mere fact that certain measures are recited in mutually different dependent claims does not indicate that a combination of these measures cannot be used to advantage.

1. A method for measuring a concentration of a sample in a sample mixture, the method comprising:
bringing the sample mixture in contact with an organic semiconductor transistor,
applying measurement signals to electrodes of the transistor for enabling measuring a drain current through the transistor,
applying a refreshment signal to a gate electrode for counteracting effects imposed on the transistor during the application of the measurement signal,
measuring the drain current,
applying an adaptation to at least one of said measurement signals for stabilizing the drain current, and
determining the concentration based on the adaptation.

2. A method as claimed in claim 1, wherein the adaptation comprises adapting a level of at least one of the measurement signals.

3. A method as claimed in claim 2, wherein the adaptation comprises adapting a level of the measurement signal for a gate electrode.

4. A method as claimed in claim 2, wherein the adaptation comprises adapting a level of the measurement signal for a source electrode.

5. A method as claimed in claim 2, wherein the adaptation comprises adapting a level of the measurement signal for a drain electrode.

6. A method as claimed in claim 1, wherein the adaptation comprises adapting a level of the refreshment signal.

7. A method as claimed in claim 1, wherein the adaptation comprises adapting a duration of the measurement signals.

8. A method as claimed in claim 1, wherein the adaptation comprises adapting a duration of the refreshment signal.

9. A detector (40) for measuring a concentration of a sample in a sample mixture, the detector (40) comprising:
an organic semiconductor transistor (10),
a source for applying:
to electrodes (11, 14, 15) of the transistor (10) a measurement signal for enabling measuring a drain current through the transistor (10), and
to a gate electrode (11) of the transistor (10) a refreshment signal for counteracting effects imposed on the transistor (10) during the application of the measurement signal,
a current detector (45) for measuring the drain current,
a compensation circuit (46) for applying an adaptation to at least one of said measurement signals for stabilizing the drain current, and
data processing means (47) for determining the concentration based on the adaptation.

10. A system (90) for measuring a concentration of a sample mixture, the system (90) comprising:
an input (91) for receiving the sample mixture
a first sector with a first detector (96) according to claim 9 for interacting with a first portion of the sample mixture and,
a second sector with:
a filter (94) for filtering the sample out of a second portion of the sample mixture to obtain a filtered sample mixture
a second detector (95) according to claim 9 for interacting with the filtered sample mixture, and
an output (97) for:
making a comparison between the adaptation to the at least one signal of the first detector (96) and the adaptation to the at least one signal of the second detector (95), and
determining and providing the concentration based on the comparison.
